(19) United States
(12) Patent Application Publication
(10) Pub. No.: US 2010/0132982 A1
(43) Pub. Date: Jun. 3, 2010

(54) Package substrate including solder resist layer having pattern parts and method of fabricating the same

(75) Inventors: Seung Hyun Cho, Seoul (KR); Je Gwang Yoo, Gyunggi-do (KR); Tae Eun Chang, Gyunggi-do (KR); Sang Soo Lee, Seoul (KR); Jung Woo Lee, Seoul (KR); Dae Young Lee, Gyunggi-do (KR); Jae Joon Lee, Gyunggi-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/379,687

(22) Filed: Feb. 26, 2009

(30) Foreign Application Priority Data
Dec. 2, 2008 (KR) 10-2008-0121243

(51) Int. Cl. H05K 1/00; B05D 5/12; H01B 13/00

(52) U.S. Cl. 174/252; 427/98.4; 156/47; 174/250

(57) ABSTRACT

Disclosed is a package substrate including a solder resist layer having pattern parts and a method of fabricating the same, in which the pattern parts are formed on the solder resist layer, thus increasing heat dissipation efficiency and minimizing the warpage of the substrate.

### CROSS REFERENCE TO RELATED APPLICATION

This application claims the benefit of Korean Patent Application No. 10-2008-0121243, filed Dec. 2, 2008, entitled “A package substrate including solder resist layers having pattern and a fabricating method the same”, which is hereby incorporated by reference in its entirety into this application.

### BACKGROUND OF THE INVENTION

1. Field of the Invention

The present invention relates to a package substrate including a solder resist layer having pattern parts and a method of fabricating the same.

2. Description of the Related Art

These days, electronic products are provided with much more electronic components due to the slimness and functionalization thereof.

However, as the number and density of electronic components which are mounted on a printed circuit board (PCB) increase, so do the consumption of power and the heat which is generated, undesirably lowering the reliability of the product and causing the warpage of the PCB due to such resulting thermal changes.

Accordingly, there have been proposed package substrates for solving problems about heat generation and warpage using a metal core having a low coefficient of thermal expansion and high heat conductivity or for mounting a heat sink on an electronic component to forcibly emit high heat from the electronic component.

FIG. 1 is a cross-sectional view showing a package substrate 10 including a metal core according to a prior art, and FIG. 2 is a cross-sectional view showing a package substrate 50 including a heat sink according to another prior art.

As shown in FIG. 1, the package substrate 10 including a metal core according to the prior art is configured such that a circuit layer 18 is formed on an insulating layer 14 having a metal core 12 inserted therein, and a first solder resist layer 20a having first openings 22a and a second solder resist layer 20b having second openings 22b are respectively formed on both surfaces of the insulating layer 14. As such, via holes formed in the insulating layer 14 are filled with plugging ink 16.

Although the package substrate 10 including a metal core according to the prior art is advantageous because heat dissipation performance is improved and warpage of the substrate is minimized thanks to the use of the metal core 12, the entire size of the package substrate 10 and the signal transfer length are increased attributable to the use of the metal core 12, making it difficult to realize the slimness of the package substrate 10.

Further, the volume of the region exposed by the first openings 22a of the first solder resist layer 20a and the volume of the region exposed by the second openings 22b of the second solder resist layer 20b on the basis of the metal core 10 which is positioned at the center of the substrate are different from each other, thereby causing warpage problems. The difference in volume occurs because the first openings 22a of the first solder resist layer 20a which is a C4 surface on which an electronic component is mounted is smaller than the second openings 22b of the second solder resist layer 20b which is a BGA surface mounted on a motherboard.

Furthermore, even when the metal core 12 for heat dissipation is used, heat is not transferred well to the metal core 12 due to the solder resist layers 20a, 20b having very low heat conductivity of 1 W/m·k, undesirably causing problems in which heat is not rapidly emitted to the outside.

As shown in FIG. 2, the package substrate 50 including a heat sink according to another prior art is configured such that a first solder resist layer 58a having first openings 60a is formed on one surface of an insulating layer 52 having a circuit layer 56, and a second solder resist layer 58b having second openings 60b is formed on the other surface thereof. As such, an electronic component 64 having a heat sink 68 is mounted on pads exposed by the first openings 60a using solder balls 61 and an underfill solution 66.

The heat generated from the electronic component 64 is transferred to the heat sink 68 attached to the upper surface of the electronic component 64 so that it can be emitted to the outside, and also, the heat is passed through the solder balls 61, the circuit layer 56 and the solder resist layers 58a, 58b and is thereby emitted to the outside.

Whereas the heat conductivity of the circuit layer 56 made of copper is very high to the level of 100˜400 W/m·k, the solder resist layers 58a, 58b have very low heat conductivity of 1 W/m·k, thereby causing problems in which heat transferred to the circuit layer 56 is not rapidly emitted to the outside.

Further, the volume of the region exposed by the first openings 60a of the first solder resist layer 58a and the volume of the region exposed by the second openings 60b of the second solder resist layer 58b on the basis of the center of the substrate are different from each other, thereby causing warpage problems.

### SUMMARY OF THE INVENTION

Intensive and extensive research culminating in the present invention was carried out to solve the problems encountered in the related art, resulting in the finding that heat transfer efficiency of a solder resist layer may be increased, thereby improving heat dissipation performance and minimizing warpage.

Accordingly, the present invention provides a package substrate including a solder resist layer having pattern parts and a method of fabricating the same, in which pattern parts are formed on the solder resist layer, thus increasing heat dissipation efficiency and minimizing warpage of the substrate.

According to a preferred embodiment of the present invention, a package substrate including a solder resist layer having pattern parts includes a base substrate having an insulating layer and a circuit layer formed on the insulating layer, and a first solder resist layer formed on a first layer of the base substrate on which an electronic component is to be mounted and having a first opening for exposing a first pad of the circuit layer formed on the first layer of the base substrate, a surface of the first solder resist layer having pattern parts.

The pattern parts of the first solder resist layer may be formed in protrusion shapes.

The pattern parts of the first solder resist layer may be of an identical shape or may be formed at equal distances from each other.

The pattern parts of the first solder resist layer may be formed to a height of 5˜10 μm from a bottom surface thereof.

The first solder resist layer may be formed using high-viscosity solder resist ink containing a filler having high heat conductivity.

The filler may include one or a mixture of two or more selected from among boron nitride, graphite, aluminum oxide, aluminum nitride, iron oxide, manganese dioxide, and titanium oxide.

Also, the package substrate may further include a second solder resist layer formed on a second layer of the base substrate which is to be mounted on a motherboard and having a second opening for exposing a second pad of the circuit layer formed on the second layer of the base substrate.

The volume of a region opened by the first opening and the pattern parts of the first solder resist layer may be identical with the volume of a region opened by the second opening of the second solder resist layer.

The electronic component may be connected to the first pad through an external connection terminal.

Also, a heat sink may be attached to an upper surface of the electronic component.

In addition, a method of fabricating the package substrate including a solder resist layer having pattern parts includes (A) preparing a base substrate including an insulating layer and a circuit layer formed on the insulating layer, and (B) forming a first solder resist layer having pattern parts on a first layer of the base substrate on which an electronic component is to be mounted, through screen printing using high-viscosity solder resist ink containing a filler having high heat conductivity.

As such, the pattern parts of the first solder resist layer may be formed in protrusion shapes.

The pattern parts of the first solder resist layer may be of an identical shape or may be formed at equal distances from each other.

The pattern parts of the solder resist layer may be formed to a height of 5˜10 μm from a bottom surface thereof.

The filler may include one or a mixture of two or more selected from among boron nitride, graphite, aluminum oxide, aluminum nitride, iron oxide, manganese dioxide, and titanium oxide.

The screen printing in (B) forming the first solder resist layer may be performed using a screen printing device including a screen frame with meshes having a size of 150˜350 μm.

The method may further include, after (B) forming the first solder resist layer, (C) forming a first opening in the first solder resist layer to expose a first pad of the circuit layer from an outermost layer of the first layer of the base substrate.

Also, the method may further include, after (C) forming the first opening, (D) forming a second solder resist layer on a second layer of the base substrate which is to be mounted on a motherboard, the second solder resist layer having a second opening for exposing a second pad of the circuit layer from an outermost layer of the second layer of the base substrate.

The volume of a region opened by the first opening and the pattern parts of the first solder resist layer may be identical with the volume of a region opened by the second opening of the second solder resist layer.

Also, the method may further include, after (C) forming the first opening, (D) mounting an electronic component on the first pad via an external connection terminal and (E) attaching a heat sink to the electronic component.

### BRIEF DESCRIPTION OF THE DRAWINGS

FIG. 1 is a cross-sectional view showing a package substrate including a metal core according to a prior art;

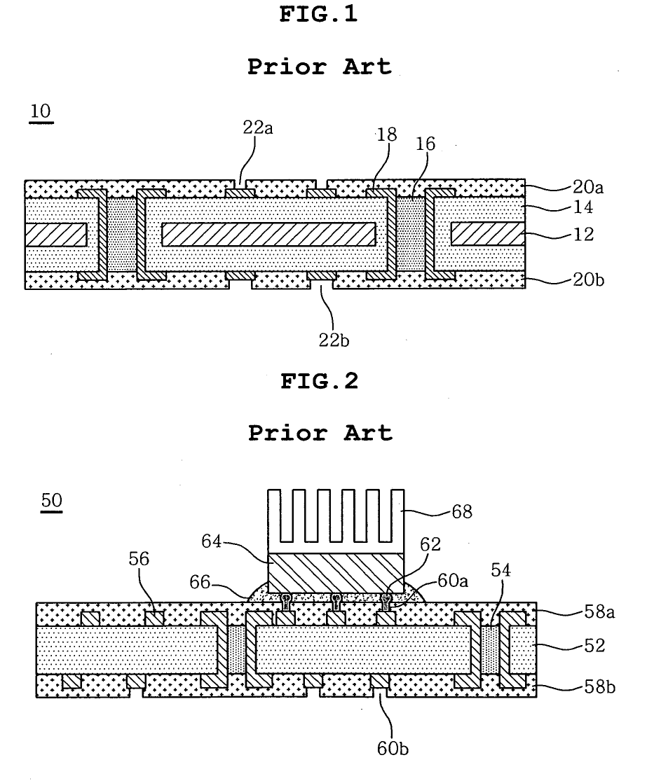

FIG. 2 is a cross-sectional view showing a package substrate including a heat sink according to another prior art;

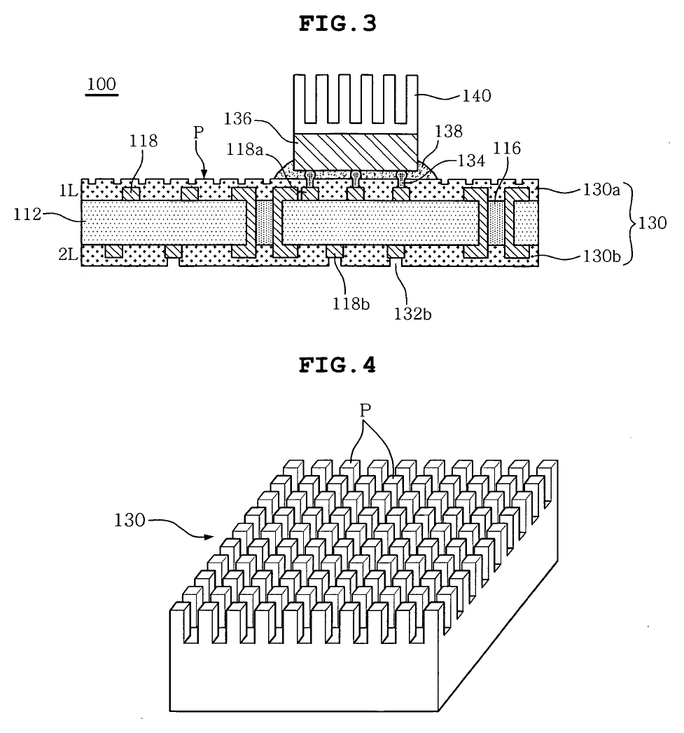

FIG. 3 is a cross-sectional view showing a package substrate including a solder resist layer having pattern parts according to a preferred embodiment of the present invention;

FIG. 4 is a perspective view showing the solder resist layer having the pattern parts of FIG. 3; and

FIGS. 5 to 10 are cross-sectional views sequentially showing a process of fabricating the package substrate including a solder resist layer having pattern parts according to the preferred embodiment of the present invention.

### DESCRIPTION OF THE PREFERRED EMBODIMENTS

The features and advantages of the present invention will be more clearly understood from the following detailed description and preferred embodiments taken in conjunction with the accompanying drawings. In the description, the terms “first”, “second” and so on do not indicate any particular amount, sequence or importance but are used only to distinguish one element from another element. Throughout the drawings, the same reference numerals refer to the same or similar elements, and redundant descriptions are omitted. Also, in the case where known techniques pertaining to the present invention are regarded as unnecessary because they make the characteristics of the invention unclear and for the sake of description, the detailed description thereof may be omitted.

Hereinafter, a detailed description will be given of a preferred embodiment of the present invention, with reference to the accompanying drawings.

Package Substrate including Solder Resist Layer having Pattern Parts

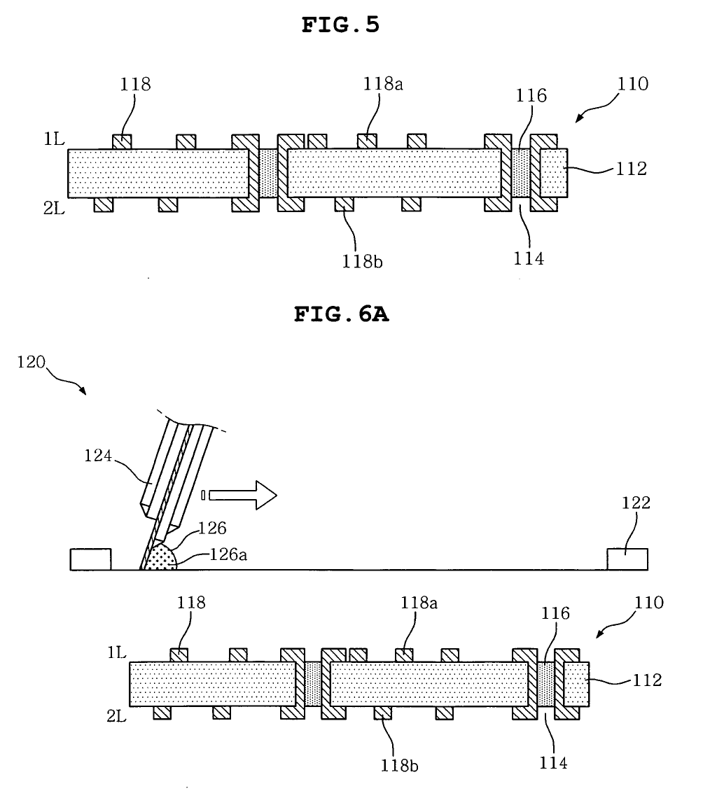

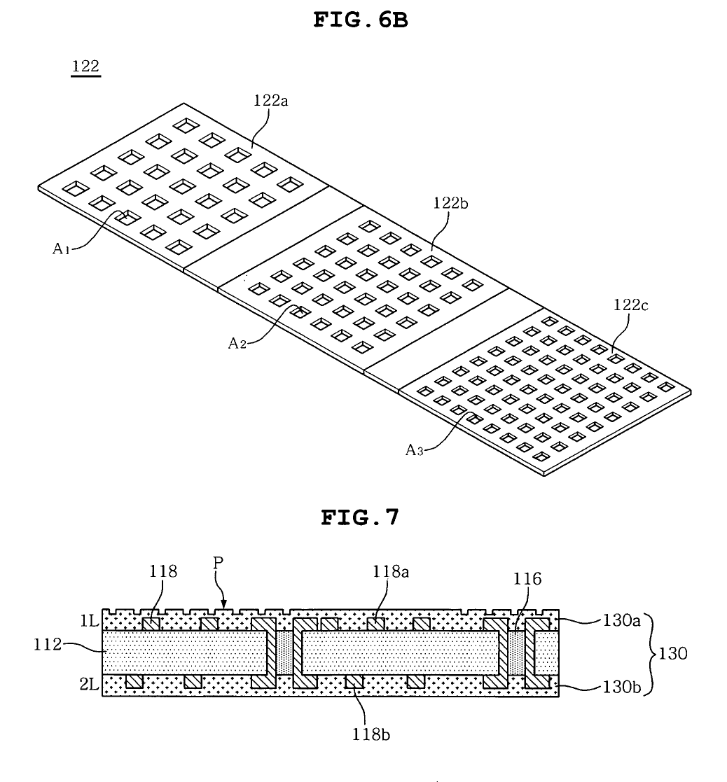

FIG. 3 is a cross-sectional view showing a package substrate including a solder resist layer having pattern parts according to a preferred embodiment of the present invention, and FIG. 4 is a perspective view showing the solder resist layer having the pattern parts of FIG. 3.

With reference to these drawings, the package substrate 100 including a solder resist layer having pattern parts according to the embodiment of the present invention is described below.

As seen in FIGS. 3 and 4, the package substrate 100 including a solder resist layer having pattern parts according to the embodiment of the present invention is configured such that a solder resist layer 130 having pattern parts P is formed on a base substrate 110.

The base substrate 110 is configured such that a circuit layer 118 is formed on either or both layers of an insulating layer 112 having via holes 114 filled with plugging ink 116.

For example, the base substrate 110 has a pair of layers 1L, 2L, in which the circuit layer 118 formed on the first layer 1L of the insulating layer 112 includes first pads 118a, and the circuit layer 118 formed on the second layer 2L of the insulating layer 112 includes second pads 118b. The first layer 1L of the base substrate 110 is a C4 surface for interconnection between an electronic component 136 and the base substrate 110, and the second layer 2L of the base substrate 110 is a BGA surface for interconnection between the base substrate 110 and a motherboard.

Although the base substrate 110 is shown as having a pair of layers 1L, 2L in FIG. 3, it is merely for illustration, and it may also be configured into a multilayer construction composed of three or more layers.

The solder resist layer 130 which is responsible for physically and chemically protecting the outermost circuit layer other than the pads, includes openings 132a, 132b for exposing the pads 118a, 118b, and, in particular, has pattern parts P in order to increase heat dissipation efficiency and minimize warpage of the substrate.

Provided on the first layer of the base substrate 110 is a first solder resist layer 130a which has the first openings 132a for exposing the first pads 118a and further has pattern parts P for increasing a contact area with the outside to improve heat dissipation efficiency. Also provided on the second layer of the base substrate 110 is a second solder resist layer 130b having the second openings 132b for exposing the second pads 118b. Although the construction in which two solder resist layers 130a, 130b are formed is illustrated in FIG. 3, a construction in which the first solder resist layer 130a is formed only on the first layer of the base substrate 110 may also be included within the scope of the present invention.

In particular, the pattern parts P may be formed on the first layer of the base substrate 110, namely on the first solder resist layer 130a corresponding to a C4 surface on which an electronic component is to be mounted. The reason is that the first openings 132a of the first solder resist layer 130a are formed to be smaller than the second openings 132b of the second solder resist layer 130b, and thus the upper/lower opened regions on the basis of the center of the base substrate 110 are controlled to have the same volume, thereby minimizing warpage of the substrate. In addition, a construction in which pattern parts P are formed on the second solder resist layer 130b may be included within the scope of the present invention. In this case, the number and size of pattern parts may be adjusted so that the opened regions have the same volume.

The pattern parts P are formed in protrusion shapes. In order to maximize heat dissipation efficiency, a plurality of pattern parts may be formed in the same shape and/or at equal distances from each other.

Further, the pattern parts P are formed to a height of 5˜10 μm from the bottom surface thereof. When the height of the pattern parts P is too low, it is difficult to improve heat dissipation performance. In contrast, when the height of the pattern parts P is too high, the thickness of the solder resist layer 130 is increased.

Moreover, the pattern parts may be naturally formed on the solder resist layer 130 through a printing process using high-viscosity solder resist ink 126 containing a filler 126a having high heat conductivity which improves heat dissipation performance and increases the viscosity of solder resist ink.

The filler 126a may include one or a mixture of two or more selected from boron nitride, graphite, aluminum oxide, aluminum nitride, iron oxide, manganese dioxide, and titanium oxide.

Method of Fabricating Package Substrate including Solder Resist Layer having Pattern Parts

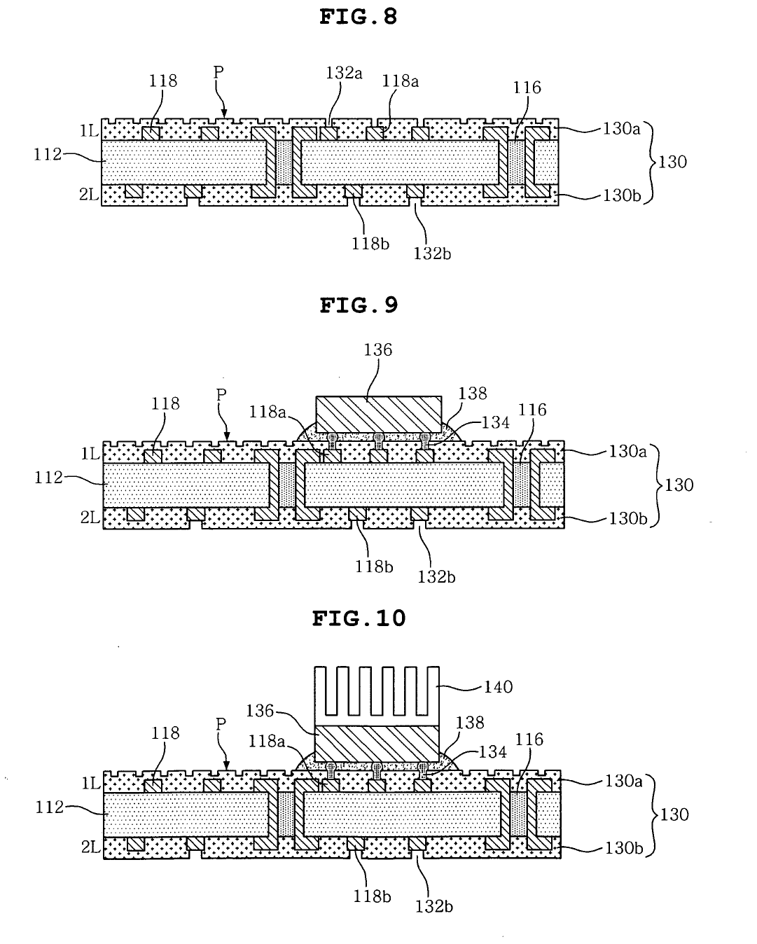

FIGS. 5 to 10 are cross-sectional views sequentially showing the process of fabricating the package substrate including the solder resist layer having the pattern parts according to the preferred embodiment of the present invention.

With reference to these drawings, the method of fabricating the package substrate including the solder resist layer having the pattern parts according to the embodiment of the present invention is described below.

As shown in FIG. 5, the base substrate 110 including the insulating layer 112 and the circuit layer 118 having the first pads 118a and/or the second pads 118b formed thereon is prepared.

The base substrate 110 is prepared by processing via holes in the insulating layer 112, forming a plating layer on the insulating layer 112 including the inner walls of the via holes 114, and patterning the plating layer, thus forming the circuit layer 118. As such, plugging ink 116 is charged in the space between the plating layers formed on the inner walls of the via holes 114.

Although the base substrate is shown as having a pair of layers in FIG. 5, it is merely for illustration, and a base substrate having a monolayer construction or a multilayer construction composed of three or more layers may also be included within the scope of the present invention.

Next, as shown in FIG. 6A, a screen printing device 120 is disposed on the base substrate 110, and high-viscosity solder resist ink 126 is prepared.

The screen printing device 120 includes a screen frame 122 with meshes A1, A2, A3 having predetermined sizes and a squeegee 124. In the present invention, because the high-viscosity solder resist ink 126 is used, the meshes of the screen frame 122 are formed to have a size larger than meshes for printing of typical solder resist ink, so that the high-viscosity solder resist ink 126 is passed through the meshes A1, A2, A3.

The high-viscosity solder resist ink 126 includes typical solder resist ink 126 and a filler 126a having high heat conductivity for improving heat dissipation performance.

Because the filler 126a is contained in the solder resist ink 126, the ink has high viscosity. In the case where the viscosity is increased, the printability of the solder resist ink is decreased. In the present invention, high-viscosity heat-dissipation solder resist ink 126 having low printability is used to form the solder resist layer through screen printing.

Specifically, for the printing of the high-viscosity heat-dissipation solder resist ink 126, the screen frame 122 with large meshes A1, A2, A3 is used. After the printing process, the heat-dissipation solder resist layer 130 having the pattern parts P which are of the same shape as the meshes A1, A2, A3 is formed by the heat-dissipation solder resist ink 126.

FIG. 6B is a perspective view showing the screen frame 122 according to the preferred embodiment of the present invention.

As the screen frame 122 according to the embodiment of the present invention, particularly useful is a plurality of screen frames 122a, 122b, 122c with meshes A1, A2, A3 having different sizes, which are integrated with each other. In order to form the solder resist layer having desired pattern parts P depending on the viscosity of the high-viscosity heat-dissipation solder resist ink 126, screen frames 122a, 122b, 122c with meshes A1, A2, A3 having a desired size may be used.

The meshes of the screen frame may have a size of 150˜350 μm.

Next, as shown in FIG. 7, the solder resist layer 130 is formed on the base substrate 110 through screen printing.

In the case where a screen printing process is performed, the first solder resist layer 130a formed on the first layer of the base substrate 110 may have the pattern parts P because of the high-viscosity solder resist ink. Although the construction in which the pattern parts P are not formed on the region where the electronic component is to be mounted is illustrated in FIG. 7, a construction in which the pattern parts P are formed on the above region may also be included within the scope of the present invention.

In addition, the second solder resist layer 130b formed on the second layer of the base substrate 110 may have no pattern parts P. This is considered to be because the area of the second openings 132b of the second solder resist layer 130b is larger than the area of the first openings 132a, and thus the opened regions are controlled to have the same volume so as to minimize the warpage of the upper and lower portions of the substrate due to the difference in volume of the opened regions. To this end, the amount of the filler which is added to the solder resist ink is reduced, so that the printability of the ink is increased, thus forming no pattern parts.

The first solder resist layer 130a and the second solder resist layer 130b may be sequentially or simultaneously formed.

Although the construction in which the first solder resist layer 130a and the second solder resist layer 130b are respectively formed on both layers of the base substrate 110 is illustrated in FIG. 7, a construction in which the solder resist layer is formed only on the first layer of the base substrate may also be included within the scope of the present invention.

Next, as shown in FIG. 8, the first openings 132a for exposing the first pads 118a and the second openings 132b for exposing the second pads 118b are respectively formed in the first solder resist layer 130a and the second solder resist layer 130b.

The openings 132a, 132b may be formed through mechanical processing such as LDA (Laser Direct Ablation).

Next, as shown in FIG. 9, external connection terminals 134 are formed on the first pads 118a, the electronic component 136 is mounted on the pads by means of the connection terminals, and then an underfill solution 138 is charged therebetween.

Finally, as shown in FIG. 10, a heat sink 140 is attached to the upper surface of the electronic component 136 using an adhesive.

As described hereinbefore, the present invention provides a package substrate including a solder resist layer having pattern parts and a fabrication method thereof. According to the present invention, the solder resist layer has pattern parts formed thereon, thus increasing the surface area thereof, thereby rapidly emitting heat from an electronic component, resulting in improved heat dissipation performance.

Also, according to the present invention, the solder resist layer having pattern parts can be formed through typical screen printing using high-viscosity solder resist ink containing a filler having high heat conductivity, thereby obviating an additional need for forming the pattern parts and improving heat dissipation performance thanks to the use of the filler.

Also, according to the present invention, the opened regions in upper and lower solder resist layers on the basis of the center of the substrate can be controlled to have the same volume, thus minimizing warpage of the substrate due to different volumes.

Although the preferred embodiment of the present invention regarding the package substrate including heat sink solder resist layers and the fabrication method thereof has been disclosed for illustrative purposes, those skilled in the art will appreciate that various modifications, additions and substitutions are possible within the scope of the invention.

1. A package substrate including a solder resist layer having pattern parts, comprising:
a base substrate having an insulating layer and a circuit layer formed on the insulating layer; and
a first solder resist layer formed on a first layer of the base substrate on which an electronic component is to be mounted and having a first opening for exposing a first pad of the circuit layer formed on the first layer of the base substrate, a surface of the first solder resist layer having pattern parts.

2. The package substrate as set forth in claim 1, wherein the pattern parts of the first solder resist layer are formed in protrusion shapes.

3. The package substrate as set forth in claim 1, wherein the pattern parts of the first solder resist layer are of an identical shape or are formed at equal distances from each other.

4. The package substrate as set forth in claim 1, wherein the pattern parts of the first solder resist layer are formed to a height of 5˜10 μm from a bottom surface thereof.

5. The package substrate as set forth in claim 1, wherein the first solder resist layer is formed using high-viscosity solder resist ink containing a filler having high heat conductivity.

6. The package substrate as set forth in claim 5, wherein the filler comprises one or a mixture of two or more selected from among boron nitride, graphite, aluminum oxide, aluminum nitride, iron oxide, manganese dioxide, and titanium oxide.

7. The package substrate as set forth in claim 1, further comprising a second solder resist layer formed on a second layer of the base substrate which is to be mounted on a motherboard and having a second opening for exposing a second pad of the circuit layer formed on the second layer of the base substrate.

8. The package substrate as set forth in claim 7, wherein a volume of a region opened by the first opening and the pattern parts of the first solder resist layer is identical with a volume of a region opened by the second opening of the second solder resist layer.

9. The package substrate as set forth in claim 1, wherein the electronic component is connected to the first pad through an external connection terminal.

10. The package substrate as set forth in claim 9, wherein a heat sink is attached to an upper surface of the electronic component.

11. A method of fabricating a package substrate including a solder resist layer having pattern parts, comprising:
preparing a base substrate including an insulating layer and a circuit layer formed on the insulating layer; and
forming a first solder resist layer having pattern parts on a first layer of the base substrate on which an electronic component is to be mounted, through screen printing using high-viscosity solder resist ink containing a filler having high heat conductivity.

12. The method as set forth in claim 11, wherein the pattern parts of the first solder resist layer are formed in protrusion shapes.

13. The method as set forth in claim 11, wherein the pattern parts of the first solder resist layer are of an identical shape or are formed at equal distances from each other.

14. The method as set forth in claim 11, wherein the pattern parts of the solder resist layer are formed to a height of 5˜10 μm from a bottom surface thereof.

15. The method as set forth in claim 11, wherein the filler comprises one or a mixture of two or more selected from among boron nitride, graphite, aluminum oxide, aluminum nitride, iron oxide, manganese dioxide, and titanium oxide.

16. The method as set forth in claim 11, wherein the screen printing in forming the first solder resist layer is performed using a screen printing device including a screen frame with meshes having a size of 150˜350 μm.

17. The method as set forth in claim 11, further comprising, after forming the first solder resist layer, forming a first opening in the first solder resist layer to expose a first pad of the circuit layer from an outermost layer of the first layer of the base substrate.

18. The method as set forth in claim 17, further comprising, after forming the first opening, forming a second solder resist layer on a second layer of the base substrate which is to be mounted on a motherboard, the second solder resist layer having a second opening for exposing a second pad of the circuit layer from an outermost layer of the second layer of the base substrate.

19. The method as set forth in claim 18, wherein a volume of a region opened by the first opening and the pattern parts of the first solder resist layer is identical with a volume of a region opened by the second opening of the second solder resist layer.

20. The method as set forth in claim 17, further comprising, after forming the first opening, mounting an electronic component on the first pad via an external connection terminal and attaching a heat sink to the electronic component.
